(19) United States
(12) Patent Application Publication
(10) Pub. No.: US 2013/0277706 A1
(43) Pub. Date: Oct. 24, 2013

(54) PACKAGE STRUCTURE OF LIGHT EMITTING DEVICE

(71) Applicant: LEXTAR ELECTRONICS CORPORATION, Hsinchu (TW)

(72) Inventors: Shing-Kuo Chen, Taipei City (TW); Bo-Yu Ko, New Taipei City (TW); Chun-Wei Wang, New Taipei City (TW)

(73) Assignee: Lextar Electronics Corporation, Hsinchu (TW)

(21) Appl. No.: 13/854,163

(22) Filed: Apr. 1, 2013

(30) Foreign Application Priority Data
Apr. 18, 2012 (TW) 101113854

(51) Int. Cl. H01L 33/64; H01L 33/62

(52) U.S. Cl. CPC H01L 33/64; H01L 33/62
USPC 257/99

(57) ABSTRACT

A package structure of a light emitting device is disclosed. The package structure includes a light emitting device, a leadframe and a cup structure. The leadframe is used for supporting the light emitting device. The leadframe has a top surface, a bottom surface and a side surface located between the top surface and the bottom surface. The side surface has a dimension in the thickness direction of the leadframe. The cup structure made of thermosetting resin is disposed on the leadframe. A sidewall of the cup structure covers the side surface of the leadframe, and has a connecting profile length in the thickness direction with respect to the side surface. The connecting profile length is larger than the dimension of the side surface in the thickness direction.

This application claims the benefit of Taiwan application Serial No. 101113854, filed Apr. 18, 2012, the subject matter of which is incorporated herein by reference.

### BACKGROUND OF THE INVENTION

1. Field of the Invention

The invention relates in general to a package structure of a semiconductor device, and more particularly to a package structure of a solid state light emitting device.

2. Description of the Related Art

Light-emitting diode (LED) emits a light by converting electric energy into photo energy. The LED, mainly composed of semiconductor, is an ideal solid state light emitting device. Conventional LED is horizontally placed on a leadframe so that better efficiency in heat dissipation can be achieved. Normally, after the LED is packaged, high-temperature baking and light-on test are performed to assure the packaging quality of the LED. However, when the temperature of environment changes, the leadframe may easily expand or contract, so as to generate a pulling force of stress on the package structure. As a result, the bonding reliability between the leadframe and the package structure deteriorates. To the worse, the pulling force of stress may even break the bonding wires, hence affecting the reliability of the LED. In addition, external moisture or harmful gases (such as sulfur gas) may infiltrate to the package structure via the edges of the leadframe. When the conventional package structure is distorted by the thermal stress, the bonding ability between the leadframe and the package structure is inadequate to resist the distortion.

### SUMMARY OF THE INVENTION

The invention is directed to a package structure of a light emitting device. The invention is capable of increasing the bonding ability between the leadframe and the cup structure and making the package structure better resist thermal stress.

According to an embodiment of the present invention, a package structure of a light emitting device is provided. The package structure includes a light emitting device, a leadframe and a cup structure. The leadframe is for supporting the light emitting device. The leadframe has a top surface, a bottom surface and a side surface located between the top surface and the bottom surface. The side surface has a dimension in a thickness direction of the leadframe. The cup structure made of thermosetting resin is disposed on the leadframe. A sidewall of the cup structure covers the side surface of the leadframe, and has a connecting profile length in the thickness direction with respect to the side surface. The connecting profile length is larger than the dimension of the side surface in the thickness direction.

According to another embodiment of the present invention, a package structure of a light emitting device is provided. The package structure includes a light emitting device, a leadframe and a cup structure. The leadframe is for supporting the light emitting device. The leadframe has a top surface, a bottom surface and a side surface located between the top surface and the bottom surface. The side surface has a first dimension in a length direction of the leadframe. The cup structure made of thermosetting resin is disposed on the leadframe. A sidewall of the cup structure covers the side surface, and has a first connecting profile length in the length direction with respect to the side surface. The first connecting profile length is larger than the first dimension.

According to an alternate embodiment of the present invention, a package structure of a light emitting device is provided. The package structure includes a light emitting device, a leadframe and a cup structure. The leadframe has a top surface, a bottom surface and a plurality of openings passing through the top surface and the bottom surface. Each opening has a first dimension in a length direction of the leadframe, and the interval between two adjacent openings in the length direction is at least larger than two times of the first dimension. The cup structure is disposed on the leadframe. A sidewall of the cup structure covers a portion of the top surface, and has a plurality of engaging members extended downward from the top surface, and the engaging members are inserted into corresponding openings.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIGS. 1A˜1D respectively show cross-sectional views of a package structure of a light emitting device according to an embodiment of the invention;

FIGS. 2A˜2E respectively show top perspective views of a package structure of a light emitting device according to an embodiment of the invention; and

FIGS. 3A and 3B respectively show a top perspective view of a package structure of a light emitting device according to an embodiment of the invention and a cross-sectional view thereof along a cross-sectional line I-I.

### DETAILED DESCRIPTION OF THE INVENTION

A package structure of a light emitting device is provided in the present embodiment. A cup structure made of thermosetting resin is formed on a leadframe by way of transfer molding method or compression molding method. The thermosetting resin, such as epoxy or silicone, has the advantages of superior heat-resistance, light reflection and stability, and not easily changing its properties or becoming deformed even in a high temperature environment, hence increasing the luminous quality of the light emitting device. Moreover, roughening treatment or patterning treatment may be applied to the side surface of the leadframe in the thickness direction to increase the contact area between the molded thermosetting resin and the leadframe (that is, the connecting profile length also increases) and accordingly increase tightness between the leadframe and the plastic cup, hence improving the packaging quality. Also, roughening treatment or patterning treatment may be applied to the side surfaces of the leadframe in the length direction or the width direction to increase the contact area between the molded thermosetting resin and the leadframe (that is, the connecting profile length also increases) and accordingly make the package structure better resist thermal stress in the horizontal direction. Therefore, the leadframe and the cup structure (such as made of thermosetting resin), will not be easily deformed by the thermal stress, and the bonding wires, when pulled by the thermal stress, will be not easily broken, and the reliability of the package structure is thus improved.

A number of embodiments are disclosed below for elaborating the invention. However, the embodiments of the invention are for detailed descriptions only, not for limiting the scope of protection of the invention.

### First Embodiment

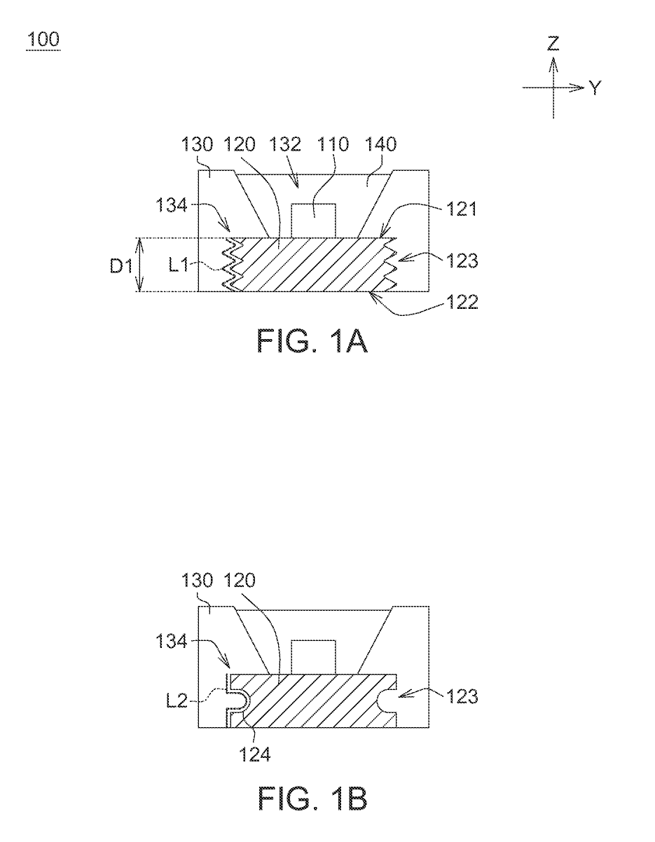

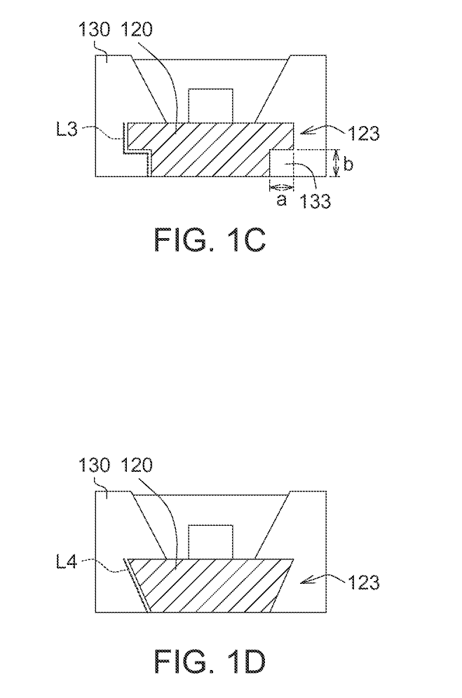

FIGS. 1A˜1D respectively show cross-sectional views of a package structure of a light emitting device according to an embodiment of the invention. Referring to FIG. 1A. The package structure 100 includes a light emitting device 110, a leadframe 120, a cup structure 130 and an encapsulation 140. The light emitting device 110 is disposed on the leadframe 120. The leadframe 120 has a top surface 121, a bottom surface 122 and a side surface 123 located between the top surface 121 and the bottom surface 122. The side surface 123 has a dimension D1 in the thickness direction (Z-axial direction) of the leadframe 120. In an embodiment, the dimension D1 of the side surface 123 is equivalent to the distance between the top surface 121 and the bottom surface 122. Besides, the cup structure 130 is disposed on the leadframe 120 and has an opening 132 for receiving the light emitting device 110. The encapsulation 140 in the opening 132 covers the surrounding of the light emitting device 110. The light emitting device 110 can be realized by a solid state light emitting device such as an LED.

To prevent moisture or harmful gases from infiltrating into the package structure 100, a sidewall 134 of the cup structure 130 (made of thermosetting resin) covers the side surface 123 and a portion of the top surface 121, and the sidewall 134 has a connecting profile length L1 with respect to the side surface 123. The connecting profile length L1 is larger than the dimension D1 of the side surface 123 in the thickness direction (Z-axial direction). As indicated in FIG. 1A, given that the dimension D1 in the thickness direction remains unchanged, the longer the connecting profile length L1, the larger the bonding area, and the more difficult it is for external moisture or harmful gases to infiltrate into the package structure 100. Thus, the reliability of bonding is improved.

Referring to FIG. 1A˜1D. A number of implementations for increasing the connecting profile length are disclosed below. The implementations may have various modifications which cannot be exemplified one by one, and the invention is not limited to the embodiments exemplified below.

In an embodiment, the side surface 123 of the leadframe 120 is a rough surface whose roughness (Ra) ranges between 0.1˜30 μm, and is preferably smaller than 18 μm, for example. As indicated in FIG. 1A, the side surface 123 is a saw-toothed surface, and the sidewall 134 of the cup structure 130 covers the saw-toothed side surface 123, so that the sidewall 134 has a saw-toothed connecting profile with respect to the side surface 123. The length of the saw-toothed connecting profile is denoted by L1.

In an embodiment, the side surface 123 of the leadframe 120 is an indented and/or a protruded surface, for example. As indicated in FIG. 1B, the center part of the side surface 123 of the leadframe 120 is indented to form a recess 124. The side surface 123 is not limited to the indented type. Alternatively, the center part of the side surface 123 is protruded to form a protrusion. The sidewall 134 of the cup structure 130 covers the indented/protruded side surface 123, so that the sidewall 134 has an indented/protruded connecting profile with respect to the side surface 123. The length of the indented/protruded connecting profile is denoted by L2.

In an embodiment, the side surface 123 of the leadframe 120 is a stepped surface, for example. The number of steps can be one or more than one, so that the width of the leadframe 120 progressively decreases at stages from top to down. The shape of the side surface 123 is not limited to be wide at the top but narrow at the bottom and may also be narrow at the top but wide at the bottom. As indicated in FIG. 1C, the sidewall 134 of the cup structure 130 covers the stepped side surface 123, so that the sidewall 134 has a stepped connecting profile with respect to the side surface 123. The length of the stepped connecting profile is denoted by L3.

In an embodiment, the side surface 123 of the leadframe 120 is an inclined surface, for example. As indicated in FIG. 1D, the side surface 123 is an inclined surface not perpendicular to the top surface 121 or the bottom surface 122, so that the width of the leadframe 120 progressively decreases from top to down. The shape of the side surface 123 is not limited to be wide at the top but narrow at the bottom and may also be narrow at the top but wide at the bottom. The sidewall 134 of the cup structure 130 covers the inclined side surface 123, so that the sidewall 134 has an inclined connecting profile with respect to the side surface 123. The length of the inclined connecting profile is denoted by L4.

Various types of connecting profile of the leadframe 120 may be formed by way of mechanical processing or etching. For example, as indicated in FIG. 1C, the T-shaped leadframe 120 may have a stepped surface 133 whose cross-sectional dimension is a×b by way of extruding or etching. Dimension a corresponds to the dimension of the leadframe 120 in the width direction (Y-axial direction), while dimension b corresponds to the dimension of the leadframe 120 in the thickness direction (Z-axial direction). The dimensions a and b of stepped surface 133 may be controlled by adjusting the contact area between the extruding tool and the leadframe 120 and adjusting the processing travel to avoid the leadframe being deformed or broken. Preferably, a<0.5*D1, b<0.5*D1, that is, the dimensions a and b are smaller than 0.5 times of the thickness dimension D1 of the leadframe 120. If the opening 132 is formed by way of etching, the ratio a:b, that is, the ratio of dimension a to dimension b, is controlled to be 1:1. Preferably, the dimensions a and b are both smaller than 0.5 times of the width dimension of the leadframe 120. In addition, when the transfer molding method or the compression molding method is used and the thickness dimension D1 of the leadframe 120 is larger than 0.15 mm, the molded package structure 100 will not be easily warped or deformed and the reliability of packaging is thus increased.

### Second Embodiment

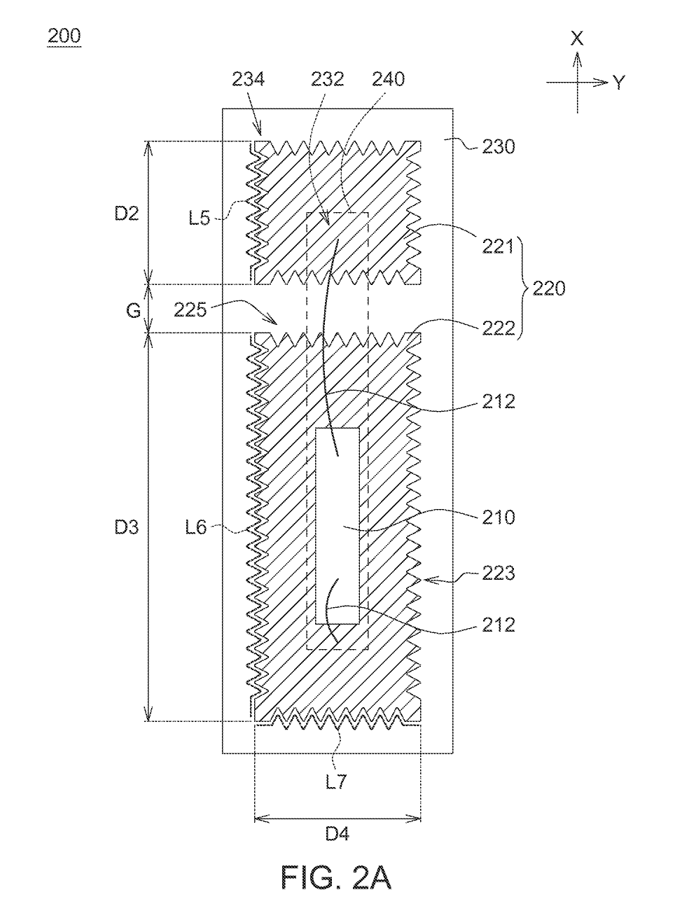

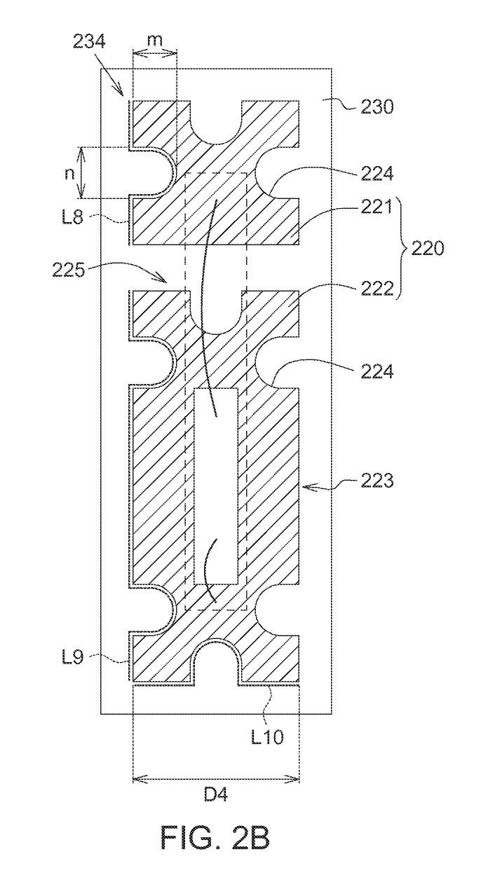

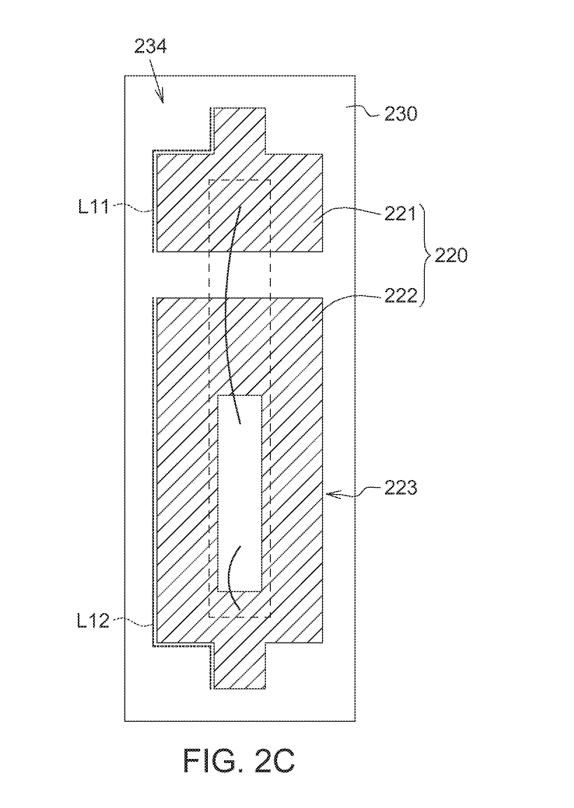

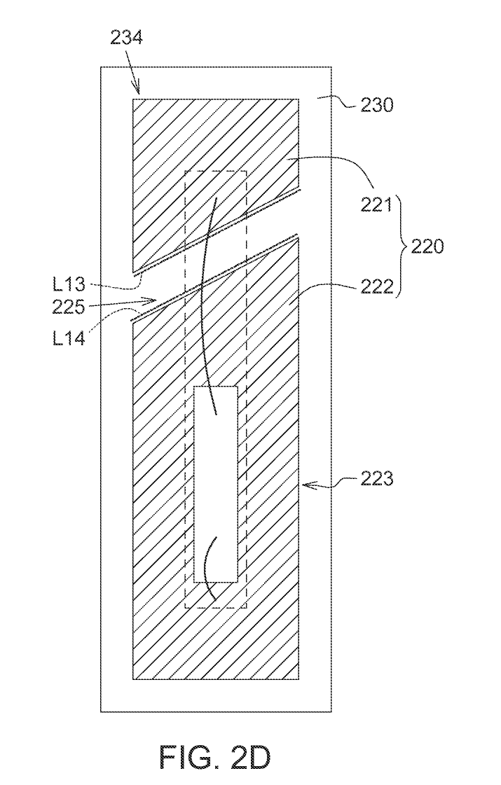

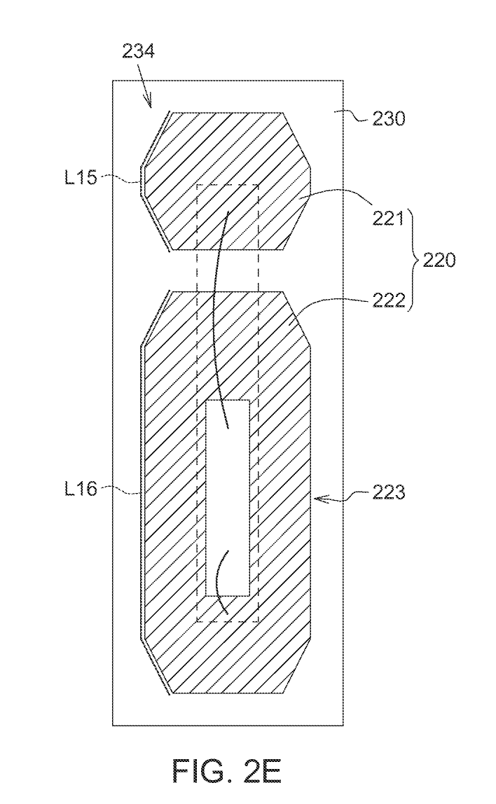

FIGS. 2A˜2E respectively show top perspective views of a package structure of a light emitting device according to an embodiment of the invention. Referring to FIG. 2A. The package structure 200 includes a light emitting device 210, a leadframe 220, a cup structure 230 and an encapsulation 240. For convenience of elaboration, in FIG. 2A, the encapsulation 240 is denoted by dotted lines. The cross-sectional views of the above embodiment show that the encapsulation 240 infused to the opening 232 of the cup structure 230 covers the surrounding of the light emitting device 210. The light emitting device 210 can be an LED, for example.

The top view shows that the leadframe 220 has an anode leadframe 221 and a cathode leadframe 222 which are separated from each other. In the present embodiment, the light emitting device 210, exemplarily but not restrictively, is disposed on the cathode leadframe 222, and the light emitting device 210 is electrically connected to the anode leadframe 221 and the cathode leadframe 222 via two wires 212 respectively, so that the light emitting device 210 may be driven by an external power to emit a light. The anode leadframe 221 and the cathode leadframe 222 respectively have a side surface 223 for connecting a top and a bottom surface. The side surface 223 of the anode leadframe 221 has a dimension D2 in the length direction (X-axial direction) of the leadframe 220, while the side surface 223 of the cathode leadframe 222 has a dimension D3 in the length direction (X-axial direction) of the leadframe 220.

To make the leadframe 220 and the cup structure 230 (such as made of thermosetting resin) better resist the thermal stress, a sidewall 234 of the cup structure 230 covers the side surface 223 of the anode leadframe 221 and the cathode leadframe 222 and a portion of the top surface. The sidewall 234 has a connecting profile length L5 with respect to the side surface 223 of the anode leadframe 221. The connecting profile length L5 is larger than the dimension D2 of the side surface 223 in the length direction. Besides, the sidewall 234 has a connecting profile length L6 with respect to the side surface 223 of the cathode leadframe 222. The connecting profile length L6 is larger than the dimension D3 of the side surface 223 in the length direction. As indicated in FIG. 2A, given that the dimension in the length direction remains unchanged, the longer the connecting profile length, the larger the bonding area. Therefore, the bonding reliability between the cup structure 230 and the leadframe 220 increases, the package structure 200 better resists the thermal stress in the length direction, and the wires 212, when pulled by the thermal stress, will not be broken easily, and the reliability of the package structure 200 is thus increased.

Likewise, the invention may also make the package structure 200 better resist the thermal stress in the width direction. Referring to FIG. 2A. Respective side surface 223 of the anode leadframe 221 and the cathode leadframe 222 has a dimension D4 in width direction (Y-axial direction) of the leadframe 220. The sidewall 234 of the cup structure 230 has a connecting profile length L7 with respect to the side surface 223 in the width direction. The connecting profile length L7 is larger than the dimension D4 of the side surface 223 in the width direction. Given that the dimension in the width direction remains unchanged, the longer the connecting profile length, the larger the bonding area. Therefore, the bonding reliability between the cup structure 230 and the leadframe 220 is increased.

Referring to FIGS. 2A˜2D. A number of implementations for increasing the connecting profile length are disclosed below. The implementations may have various modifications which cannot be exemplified one by one, and the invention is not limited to the embodiments exemplified below.

In an embodiment, the side surface 223 of the leadframe 220 is a rough surface (such as a saw-toothed surface) whose roughness (Ra) ranges between 0.1˜30 μm, and is preferably smaller than 18 μm, for example. As indicated in FIG. 2A, the rough surface of side surface 223 is saw-toothed, the sidewall 234 of the cup structure 230 covers the saw-toothed side surface 223, and the sidewall 234 has a saw-toothed connecting profile with respect to the side surface 223. A gap G is formed between the anode leadframe 221 and the cathode leadframe 222. When the cup structure 230 is formed, the gap is filled with thermosetting resin. To enhance the bonding between the side surface 225 of the leadframe and the thermosetting resin, the side surface 225 in the vicinity of the gap is saw-toothed.

In an embodiment, the side surface 223 of the leadframe 220 is an indented and/or protruded surface. As indicated in FIG. 2B, the peripheral of the side surface 223 of the leadframe 220 is indented to form a plurality of recesses 224. Alternatively, the peripheral of the side surface 223 of the leadframe 220 is protruded to form a plurality of protrusions. The sidewall 234 of the cup structure 230 covers the indented/protruded side surface 223, so that the sidewall 234 has an indented/protruded connecting profile with respect to the side surface 223. The indented/protruded connecting profile has lengths L8, L9 and L10, respectively. As mentioned above, to enhance the bonding between the side surface 225 of the leadframe and the thermosetting resin, the side surface 225 in the vicinity of the gap between the anode leadframe 221 and the cathode leadframe 222 is an indented suface and/or a protruded surface.

In an embodiment, the side surface 223 of the leadframe 220 is a stepped surface. The number of steps can be one or more than one, so that the width of the leadframe 220 progressively decreases at stages from the middle to the two sides. The shape of the side surface 223 is not limited to be wide in the middle but narrow in the two sides, and may also be narrow at the middle but wide in the two sides. As indicated in FIG. 2C, the sidewall 234 of the cup structure 230 covers the stepped side surface 223, so that the sidewall 234 has a stepped connecting profile with respect to the side surface 223. The stepped connecting profile has lengths L11 and L12, respectively.

In an embodiment as indicated in FIGS. 2D and 2E, the side surface 223 of the leadframe 220 is an inclined surface. That is, the side surface 223 is an inclined surface in the width direction (FIG. 2D) or in the length direction (FIG. 2E), so that the shape of the leadframe 220 is a trapezoid or a scalene quadrilateral. The shape of the leadframe 220 is not limited to a quadrilateral and may also be realize by a polygon. The sidewall 234 of the cup structure 230 covers the inclined side surface 223, so that the sidewall 234 has an inclined connecting profile with respect to the side surface 223. The inclined connecting profile has lengths L13, L14, L15, and L16, respectively. As disclosed above, the side surface 225 in the vicinity of the gap between the anode leadframe 221 and the cathode leadframe 222 may be an inclined surface so that the bonding reliability between the side surface 225 and thermosetting resin can be enhanced.

The connecting profiles of the leadframe 220 may by formed by way of mechanical processing or etching. For example, as indicated in FIG. 2B, the leadframe 220 may have a plurality of recesses 224 whose dimension is m×n by way of extruding or etching. The dimensions m and n of the recesses 224 may be controlled by adjusting the contact area between the extruding tool and the leadframe 220 to avoid the molded package structure being warped or breaking up during the extruding process. Preferably, 0.9*D1<m<0.5*D4, 0.9*D1<n<0.5*D4, that is, m, n are larger than 0.9 times of the thickness dimension D1 of the leadframe 220 but are smaller than 0.5 times of the width dimension D4 of the leadframe 220.

### Third Embodiment

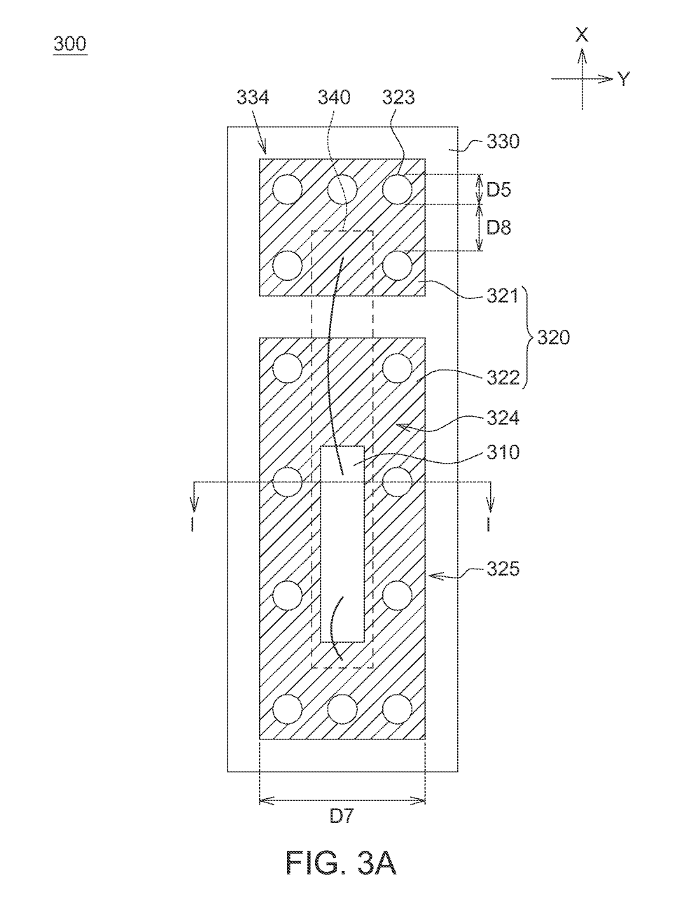

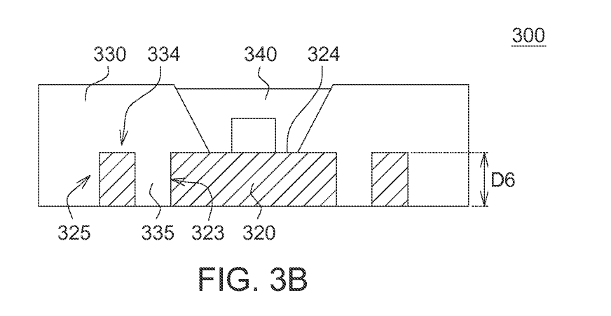

Referring to FIGS. 3A and 3B, a top perspective view and a cross-sectional view of a package structure of a light emitting device according to an embodiment of the invention are respectively shown. The cross-sectional view is viewed along a cross-sectional line I-I. The package structure 300 of the present embodiment includes a light emitting device 310, a leadframe 320, a cup structure 330 and an encapsulation 340. The present embodiment is different from the second embodiment in that the leadframe 320 has a plurality of openings 323 passing through the top and the bottom surfaces to enhance the bonding ability between the leadframe 320 and the cup structure 330. Like the bonding enhancing mechanism used in the second embodiment, the bonding enhancing mechanism used in the present embodiment also makes the package structure 300 better resist the thermal stress.

Referring to FIG. 3A, the anode leadframe 321 and the cathode leadframe 322 respectively have a plurality of openings 323 passing through the top and the bottom surfaces. Each opening 323 has a first dimension D5 in the length direction (X-axial direction) of the leadframe 320. Referring to FIG. 3B. The cup structure 330 is disposed on the leadframe 320. The sidewall 334 of the cup structure 330 covers a portion of the top surface 324 and the side surface 325, and has a plurality of engaging members 335 extended downward from the top surface 324 and inserted into corresponding openings 323.

The openings 323 of the leadframe 320 may be formed by way of mechanical processing or etching. If the openings 323 are formed by way of punching, the diameter of the punch tool is larger than the thickness dimension D6 of the leadframe 320 (FIG. 3B), and preferably is larger than 0.9 times of the thickness dimension of the leadframe 320 to avoid having difficulties with processing the openings 323 being too small or the leadframe 320 being too thick. In addition, the diameter of the punching tool is smaller than 0.5 times of the width dimension D7 of the leadframe 320 to avoid the openings 323 being too large and warped after the leadframe is punched. The conditions of the above dimensions are expressed as: 0.9*D6<D5<0.5*D7. In addition, the interval D8 between two adjacent openings 323 in the length direction is at least larger than two times of the dimension D5 of the opening 323, that is, D8>2*D5, to avoid the openings 323 being too close to each other and breaking up during the punching process. When the transfer molding method or the compression molding method is used and the thickness of the leadframe 320 is larger than 0.15 mm, the molded package structure 300 will not be easily warped or deformed, and the reliability of packaging is thus increased.

In the present embodiment, circular openings are used as an exemplification. However, the openings are not limited to circular holes, and may be realized by elliptical holes, triangular holes, quadrilateral holes or polygon holes, for example.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure of a light emitting device, comprising:
a light emitting device;
a leadframe for supporting the light emitting device, wherein the leadframe has a top surface, a bottom surface and a side surface located between the top surface and the bottom surface and having a dimension in a thickness direction of the leadframe; and
a cup structure made of thermosetting resin and disposed on the leadframe, wherein a sidewall of the cup structure covers the side surface and has a connecting profile length in the thickness direction with respect to the side surface, and the connecting profile length is larger than the dimension of the side surface.

2. The package structure according to claim 1, wherein the side surface is a rough surface whose roughness ranges between 0.1˜30 μm, and the sidewall has a saw-toothed connecting profile with respect to the side surface.

3. The package structure according to claim 1, wherein the side surface is an indented and/or a protruded surface, and the sidewall has an indented/protruded connecting profile with respect to the side surface.

4. The package structure according to claim 1, wherein the side surface is a stepped surface, and the sidewall has a stepped connecting profile with respect to the side surface, the stepped surface has a first and a second dimensions respectively in the thickness and width directions of the leadframe, the first and the second dimensions both are smaller than 0.5 times of the thickness dimension of the leadframe.

5. The package structure according to claim 1, wherein the side surface is an inclined surface, and the sidewall has an inclined connecting profile with respect to the side surface.

6. A package structure of a light emitting device, comprising:
a light emitting device;
a leadframe for supporting the light emitting device, wherein the leadframe has a top surface, a bottom surface and a side surface located between the top surface and the bottom surface and having a first dimension in a length direction of the leadframe; and
a cup structure made of thermosetting resin and disposed on the leadframe, wherein a sidewall of the cup structure covers the side surface and has a first connecting profile length in the length direction with respect to the side surface, and the first connecting profile length is larger than the first dimension of the side surface.

7. The package structure according to claim 6, wherein the side surface is a rough surface whose roughness ranges between 0.1˜30 μm, and the sidewall has a saw-toothed connecting profile with respect to the side surface.

8. The package structure according to claim 6, wherein the side surface is an indented and/or a protruded surface, and the sidewall has an indented/protruded connecting profile with respect to the side surface, and when the leadframe has a recess on the side surface, the recess has a second dimension and a third dimension respectively in the length and width directions of the leadframe, and the second dimension and the third dimension both are larger than 0.9 times of thickness dimension of the leadframe but smaller than 0.5 times of width dimension of the leadframe.

9. The package structure according to claim 6, wherein the side surface is a stepped surface, and the sidewall has a stepped connecting profile with respect to the side surface.

10. The package structure according to claim 6, wherein the side surface is an inclined surface, and the sidewall has an inclined connecting profile with respect to the side surface.

11. The package structure according to claim 6, wherein the side surface has a fourth dimension in width direction of the leadframe and the sidewall has a second connecting profile length in the width direction with respect to the side surface, and the second connecting profile length is larger than the fourth dimension.

12. The package structure according to claim 11, wherein the side surface is a rough surface whose roughness ranges between 0.1˜30 μm, and the sidewall has a saw-toothed connecting profile with respect to the side surface.

13. The package structure according to claim 11, wherein the side surface is an indented and/or a protruded surface, the sidewall has an indented/protruded connecting profile with respect to the side surface, and when the leadframe has a recess on the side surface, the recess has a fifth dimension and a sixth dimension respectively in the length and the width direction of the leadframe, and the fifth and the sixth dimensions both are larger than 0.9 times of thickness dimension of the leadframe but smaller than 0.5 times of width dimension of the leadframe.

14. The package structure according to claim 11, wherein the side surface is a stepped surface, and the sidewall has a stepped connecting profile with respect to the side surface.

15. The package structure according to claim 11, wherein the side surface is an inclined surface, and the sidewall has an inclined connecting profile with respect to the side surface.

16. A package structure of a light emitting device, comprising:
a light emitting device;
a leadframe for supporting the light emitting device, wherein the leadframe has a top surface, a bottom surface and a plurality of openings passing through the top surface and the bottom surface, each opening has a first dimension in a length direction of the leadframe, and the interval between two adjacent openings in the length direction is at least larger than two times of the first dimension; and
a cup structure made of thermosetting resin and disposed on the leadframe, wherein a sidewall of the cup structure covers a portion of the top surface and has a plurality of engaging members extended downward from the top surface and inserted into corresponding openings.

17. The package structure according to claim 16, wherein the openings have a second dimension in thickness direction of the leadframe, and the first dimension is larger than 0.9 times of the second dimension but smaller than 0.5 times of width dimension of the leadframe.

18. The package structure according to claim 16, wherein the openings are circular holes, elliptical holes or polygonal holes.
